(19) United States
(12) Patent Application Publication
(10) Pub. No.: US 2025/0063930 A1
(43) Pub. Date: Feb. 20, 2025

(54) METHOD FOR MANUFACTURING AN INTRINSICALLY STRETCHABLE ORGANIC SOLAR CELL

(71) Applicant: Korea Advanced Institute of Science and Technology, Daejeon (KR)

(72) Inventors: Bum Joon KIM, Daejeon (KR); Jung-Yong LEE, Daejeon (KR); Jong Hyeon NOH, Daejeon (KR); Geon U KIM, Daejeon (KR)

(21) Appl. No.: 18/913,477

(22) Filed: Oct. 11, 2024

Related U.S. Application Data
(63) Continuation-in-part of application No. 17/966,616, filed on Oct. 14, 2022.
Application No. 17/966,616 is a continuation-in-part of application No. PCT/KR2021/004191, filed on Apr. 5, 2021.

(30) Foreign Application Priority Data
Apr. 17, 2020 (KR) 10-2020-0046513
Feb. 26, 2021 (KR) 10-2021-0026367

(51) Int. Cl. H10K 71/12; H10K 30/50; H10K 30/81

(52) U.S. Cl. CPC H10K 71/12; H10K 30/50; H10K 30/81

(57) ABSTRACT

Provided is a method for manufacturing an intrinsically stretchable organic solar cell, a manufacturing method thereof, and an electronic device comprising the same. The intrinsically stretchable organic solar cell of the present invention is characterized that wherein excellent interfacial bonding among stretchable constituent elements constituting each layer is induced so that the constituent elements are seamlessly integrated into a single system, thereby ensuring excellent initial power conversion efficiency (PCE), and mechanical robustness showing that 70% or more of initial PCE is maintained in spite of repetitive tensile strains. Thus, the organic solar cell is useful for an electronic device applied to any one selected from a group consisting of sensors, electronic skins, flexible displays, and stretchable displays.

### TECHNICAL FIELD

The present invention relates to a method for manufacturing an intrinsically stretchable organic solar cell, and, more particularly, to the intrinsically stretchable organic solar cell comprising an electrical charge transport layer, an organic photoactive layer composed of a conjugated polymer, and an electrode layer composed of a stretchable conductor, which are piled up from an elastic substrate, wherein excellent interfacial bonding among stretchable constituent elements constituting each layer is seamlessly integrated into a single system, thereby ensuring excellent initial power conversion efficiency (PCE), and mechanical stretchability showing that 70% or more of initial PCE is maintained in spite of repetitive tensile strains.

### BACKGROUND ART

Since an organic solar cell is advantageous in that it is possible to manufacture it more easily and cheaply than an inorganic solar cell like an existing silicone solar cell, the organic solar cell has been noticed as a next generation solar cell and has recently become the center of high interest as an energy source for stretchable electronic devices.

The stretchable electronic devices mean elements which don't show a lowering of electrical physical properties thanks to their own elasticity to a tensile stress even in a state of a tensile strain occurring. Representative practical examples include wearable computers, electronic skins (E-skin), and so on. The current electronic devices based on a silicon and glass substrate cannot function as devices any longer because a crack occurs even at a small tensile stress in the light of the properties of an inorganic substance, and thus in order to embody next generation stretchable electronic devices, there is a necessity for developing novel materials and approaching a new course of studies.

Various studies intended for embodying these stretchable electronic devices have been carried out, and as one example thereof, after an element based on a thin film of an inorganic substance, like an existing silicon or semiconductor compound, is manufactured into a thin film on a silicon-based elastic body substrate to which a tensile strain is previously applied, when the thin film returns into its original state, the element in the thin film form in the upper direction forms a periodic wave pattern while coming under pressure.

However, although a limit of the tensile strain of the silicon semiconductor thin film can be improved up to about 100% through this method, breaking of the material may finally occur under the condition of a larger strain due to a heterojunction structure between the thin film and the elastic substrate, and there is no structural compatibility concerning the existing two-dimensional plane elements.

The other approach for providing devices with stretchability is a pre-stretching or buckling method as publicly known through Non-Patent Document 1, and this method is that under the condition of no external strains, a device is compressed along a stretching direction, and when a strain is applied, the compression is released, and the device appears to be stretchable uniaxially.

However, although the method can entirely improve stretchability of the device, a manufacturing process is complex, and in particular, in case of the pre-stretching method, it is problematic in that a tensile direction appears to be stretchable only in a predetermined direction, and the buckling method is an approach in a structural aspect attended by a structural strain showing that an light receiving area reduces, and the situation is also that a material has completely no influence on stretchable constituent elements because only a fixed part is provided with stretchability.

Furthermore, Patent Document 1 reports that a stretchable light-concentrating type solar cell disclosed therein is advantageous in that the solar cell comprises: a base layer consisting of a stretchable base part and a light guide base part; a solar electric cell installed on the light guide base part; an insulating layer which performs insulation so as to cause the solar cell to be sealed; and a wiring layer which electrically connects the solar electric cell to the insulating layer, wherein the light-concentrating type solar cell and a light guide material are installed at the stretchable material so that light-concentrating efficiency increases, and the freedom degree of a design is improved by a stretchable feature, and accordingly, the solar cell can be used in various devices.

A conventional approach for providing the aforesaid stretchable electronics is a method of introducing a modified structure into the existing material, or an island parts-interconnecting method of causing a circuit connection line to be stretchable, and it is problematic in that since only a part of constitutions of the elements is provided with stretchability, efficiency reduces largely under the condition of repetitive tensile strains.

Accordingly, in order for an ultimate stretchable electronic devices to be applied to a wearable electronic device, like a wearable computer, an E-skin, and so on, the electronic devices should have satisfactory high PCE performance as well as high output per weight to repetitive tensile strains, and excellent robustness.

However, in the organic solar cells of high efficiency which have been reported until today, have been mostly used hard substrates like ITO-coated glass, and vapor-deposited metal electrodes, so there has been still a limit in stretchability to take aim at applying them to stretchable electronic devices. Accordingly, studies for developing organic solar cells having stretchability and mechanical stretchability while realizing high PCE performance have been actively carried out, but organic solar cells haven't still reached realizing a physical property in a standard that enables them to be applied to wearable electronics, like wearable computers, E-skins, and so on.

Thus, as a result of the present inventors' efforts for developing an intrinsically stretchable organic solar cell which causes all the constituent materials constituting the organic solar cell to have stretchability, the present invention has been completed in such a manner as to seamlessly integrate stretchable constituent elements into a single system through excellent interfacial combinations among the stretchable constituent elements constituting each layer by comprising an electrical charge transport layer, an organic photoactive layer composed of a conjugated polymer, and an electrode layer composed of a stretchable conductor, which are piled up from an elastic substrate, thereby confirming high PCE, and mechanical stretchability showing that 70% or more of initial PCE is maintained in spite of repetitive tensile strains.

### PRIOR ART DOCUMENT

### Patent Document

(Patent Document 1) Korean Patent Reg. No. 1899253 (officially announced on Oct. 31, 2018)

### Non-Patent Document

(Non-Patent Document 1) Nature Photonics, 2013, 7, 811-816.

### DETAILED DESCRIPTION OF THE INVENTION

### Technical Problem

An object of the present invention is to provide an intrinsically stretchable organic solar cell securing high power conversion efficiency (PCE) performance and mechanical stretchability.

Another object of the present invention is to provide a method of manufacturing an intrinsically stretchable organic solar cell.

The other object of the present invention is to provide an electronic device comprising an intrinsically stretchable organic solar cell.

### Solution for Solving the Problem

In order to achieve the objects, the present invention provides an intrinsically stretchable organic solar cell, comprising an electrical charge transport layer, an organic photoactive layer composed of a conjugated polymer, and an electrode layer composed of a stretchable conductor, which are piled up from an elastic substrate.

In the above, the electrical charge transport layer may comprise: a transport layer composed of an organic material; a transport layer composed of an inorganic material; and a transport layer composed of a mixture of the organic material and the inorganic material, more preferably, the electrical charge transport layer may comprise a transport layer composed of an organic material having a single form consisting of one selected from a polymeric hole transport layer, a small molecular hole transport layer, a polymeric electron transport layer, and a small molecular electron transport layer, or having a mixed form thereof.

Furthermore, in the above, the electrode layer may comprise a first electrode layer and a second electrode layer composed of a stretchable conductor selected from a polymer or a stretchable metal.

The intrinsically stretchable organic solar cell of the present invention may have a normal structure or an inverted structure with respect to a conventional structure of organic solar cells in which a plurality of layers are formed centering around a photoactive layer formed above a substrate, a position of the polymeric or small molecular hole transport layer, or the polymeric or small molecular electron transport layer may be inverted in such a manner that its upper part and lower part are inverted each other, and the first electrode layer and the second electrode layer constituting the electrode layer may be also inverted into a bottom electrode and a top electrode.

More specifically, the intrinsically stretchable organic solar cell according to an embodiment of the present invention is described on a structure in which the first electrode layer, the hole transport layer, the photoactive layer, the electron transport layer, and the second electrode layer are bonded in an elastic substrate, but the positions of the first electrode layer and the second electrode layer are inverted each other, or the positions of the hole transport layer and the electron transport layer are inverted each other.

With respect to the intrinsically stretchable organic solar cell of the present invention, the term “stretchable” is not limited to one direction or a predetermined specific direction but should be construed as having the properties of stretchability and restoring force in a standard that can make a strain realized freely and easily in biaxial or multi-axial directions, or regardless of a direction. These properties are realized in such a manner that each layer constituting the intrinsically stretchable organic solar cell of the present invention is composed of a stretchable material so that constituent elements of each layer are seamlessly integrated into a single system as excellent interfacial bonding among them is induced.

Also, the stretchable property of the intrinsically stretchable organic solar cell of the present invention provides mechanical stretchability which shows that 70% or more, preferably, 80% or more of initial PCE is maintained in a tensile repetition experiment on the basis of repetition 100 to 10,000 times.

Most specifically, although the embodiment of the present invention provides an organic solar cell which shows that 11% or more excellent PCE is realized, and 80% or more of the initial PCE is maintained in a tensile repetition experiment on the basis of repetition 100 to 10,000 times under the condition of 10% tensile strain, exemplary embodiments are not limited thereto, and after organic solar cells are manufactured, if they each maintain 70% or more of the initial PCE in in the tensile repetition experiment on the basis of repetition 100 to 10,000 times, all the organic solar cells having a certain level of PCE performance be included. The PCE performance may include an organic solar cell of 5% or more, preferably 10% or more.

### Effect of the Invention

The intrinsically stretchable organic solar cell according to the present invention can achieve durability which shows that 70% or more of initial PCE is maintained despite repetitive tensile strains while satisfying excellent PCE performance, because stretchable constituent elements of each layer are seamlessly integrated into a single system through a smooth interfacial combination among them.

The manufacturing method of the intrinsically stretchable organic solar cell according to the present invention can realize low energy consumption because most of the processes are performed using an atmospheric-pressure solution process, and thus no conditions of a high temperature, a high vacuum, and so on are required, and the manufacturing method can secure excellent reproducibility, and yield owing to the integrated processes, and can improve stretchability and mechanical endurance by improving adhesive strength among layers constituting the organic solar cell, and uniformity of each layer.

Also, the intrinsically stretchable organic solar cell according to the present invention can be applied to various electronic devices, like various kinds of sensors including strain sensors, temperature sensors, pressure sensors, optical sensors, vibration sensors, biosensors, etc., electronic skins, flexible displays, stretchable displays, and so on by being included as a power source, and in particular, the intrinsically stretchable organic solar cell can be usefully applied to clothing type, accessory type, or body attachment type wearable electronic devices aimed at skins, fibers, or curved surfaces.

### BRIEF DESCRIPTION OF THE DRAWINGS

FIG. 1A to FIG. 1C show image results from an atomic force microscope (AFM) concerning surface roughness according to each elastic substrate derived from an intrinsically stretchable organic solar cell of the present invention;

FIG. 2 shows a result of transmittance according to each elastic substrate of the present invention;

FIG. 3 shows resistance values resulting from initial tensile strains according to conditions for forming a first electrode layer of the present invention;

FIG. 4 shows a result of relative resistance values resulting from the tensile repetition number of times according to the conditions for forming the first electrode layer shown in FIG. 3;

FIG. 5 shows a result of current density (mAcm⁻²) to voltage of the organic solar cell according to each constitution of a photoactive layer manufactured from the present invention;

FIG. 6 shows a result of power conversion efficiency (PCE) performance (%) resulting from the intensity of tensile strain (tensile external force) with respect to the organic solar cell according to each constitution of the photoactive layer manufactured from the present invention;

FIG. 7 shows a result of PCE (%) resulting from a tensile repetition experiment in a horizontal direction under fixed tensile strain with respect to the organic solar cell according to each constitution of the photoactive layer manufactured from the present invention;

FIG. 8 shows a result of PCE (%) resulting from a tensile repetition experiment in a vertical direction under fixed tensile strain with respect to the organic solar cell according to each constitution of the photoactive layer manufactured from the present invention;

FIG. 9 shows tensile stress to strain curves concerning tensile strain according to respective contents of acceptors of the photoactive layer derived from the organic solar cell of the present invention;

FIG. 10 shows a result of the elastic modulus concerning the tensile strain according to the respective contents of the acceptors of the photoactive layer derived from the organic solar cell of the present invention;

FIG. 11 shows a result of fracture strains concerning the tensile strain according to the respective contents of the acceptors of the photoactive layer derived from the organic solar cell of the present invention;

FIG. 12 shows perspective views of 3D models for a single film composed of the photoactive layer (PM6:Y7) of the present invention, and for a film in which the photoactive layer (PM6:Y7) is attached onto a surface composed of TPU/PEDOT:PSS, showing the result of a finite element analysis for materializing a tensile stress distribution resulting from elongation.

FIG. 13 shows stress to strain curves of the films shown in FIG. 12;

FIG. 14 illustrates a conceptual view concerning making of a crack formed by a progressive tensile repetition experiment for the organic solar cell comprising the film in which the photoactive layer (PM6:Y7) is attached onto the surface composed of TPU/PEDOT:PSS;

FIG. 15 shows changes in resistance values concerning tensile strain according to each material of a second electrode layer shown in the intrinsically stretchable organic solar cell of the present invention;

FIG. 16 shows changes in resistance values concerning the repetition number of times in a state of the tensile strain shown in FIG. 15 being fixed to be 20%;

FIG. 17 illustrates, in steps, a manufacturing process of the intrinsically stretchable organic solar cell of the present invention; and

FIG. 18 shows a sectional image of the intrinsically stretchable organic solar cell produced by the manufacturing method shown in FIG. 17.

### MODE FOR CARRYING OUT THE INVENTION

Hereinafter, with respect to an intrinsically stretchable organic solar cell of the present invention, the features according to each constitution are described in detail.

### 1) Elastic Substrate

In order to improve efficiency of an intrinsically stretchable organic solar cell of the present invention, it is preferable that an elastic substrate has low surface roughness.

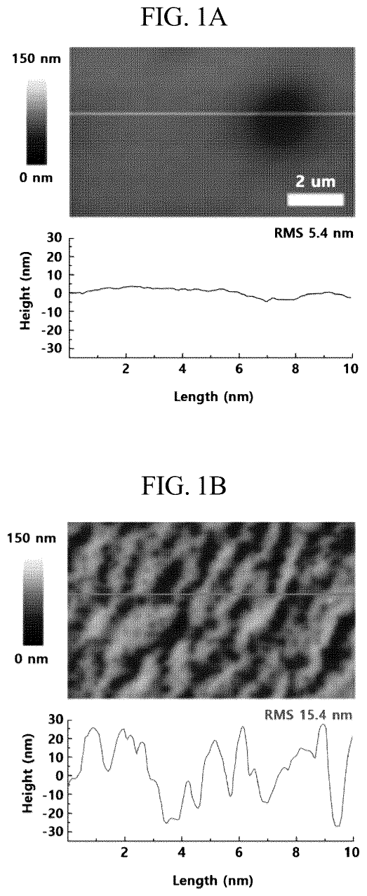

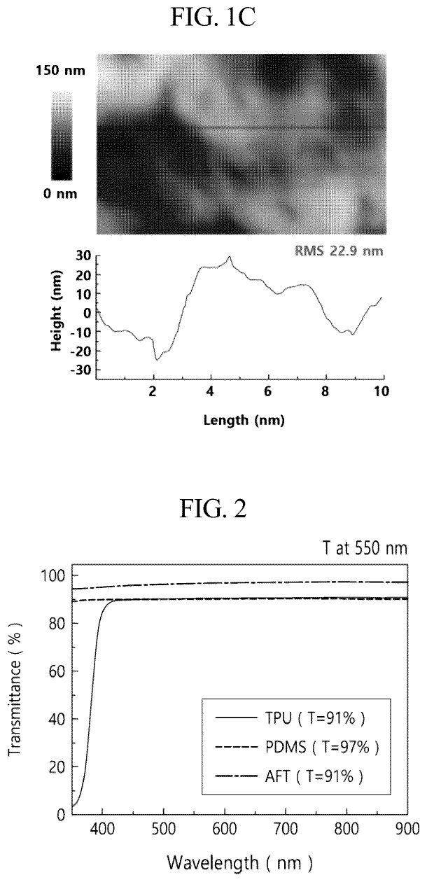

FIG. 1A to FIG. 1C show image results from an atomic force microscope (AFM) concerning surface roughness according to each elastic substrate of the present invention, wherein it can be confirmed that when the substrates have a surface roughness RMS of 5.4 nm (A), they show as having their respective uniform surfaces, whereas when the surface roughness RMS is 15.4 nm (B), and 22.9 nm (C), the surfaces are not uniform. Based on this result, with respect to the elastic substrates according to the present invention, it is preferable to use a substrate having surface roughness of 15 nm or below, more preferably, 5 to 10 nm, the most preferably, 2 to 10 nm.

Furthermore, in order for the elastic substrates according to the present invention to have transparency and rigidity to a degree that can make them substituted for a conventional indium tin oxide (ITO)-coated glass substrate, the elastic substrates should satisfy high transmittance of visible light and should satisfy high stretchability and mechanical endurance.

FIG. 2 shows a result of transmittance according to each elastic substrate of the present invention, and as preferable one example, all the thermoplastic polyurethane (TPU) substrate, the polydemethylsiloxane (PDMS) substrate, and the acryl foam tape (AFT) substrate show 90% or more high light transmittance in a region of 380 to 900 nm, and in particular, it can be confirmed that the TPU substrate shows a strong absorption property in an ultraviolet region of 380 nm or below, so potential photodecomposition of an organic bulk heterojunction layer of an adjacent photoactive layer can be controlled, and photo-stability of the organic solar cell can be improved.

Furthermore, each elastic substrate according to the present invention is required to have satisfactory wettability so as to be combined with an adjacent upper layer (e.g., a first electrode layer or a second electrode layer) without a defect.

Accordingly, with respect to the elastic substrates, it is preferable to use a material having a water contact angle of 100° or below. At this time, when the water contact angle exceeds 100°, since formation of the upper layer is not smoothly carried out due to a hydrophobic surface, and an interfacial adhesive property becomes low, detachment from the upper layer may occur. Since the more the water contact angle of each elastic substrate is low, the more efficiency of a device is advantageous, it is preferable to a material having a water contact angle of 70° to 100°, more preferably, 0° to 100°.

Furthermore, in order to improve wettability between the substrate and the layer formed thereon, an elastic substrate treated by surface plasma may be used.

In an embodiment of the present invention, although thermoplastic polyurethane (TPU) is used as the best preferable material for the elastic substrate, if the same material is beyond the requirements for surface roughness or a water contact angle, layers which will be formed to be piled up from the substrate will not be uniformly formed, and in particular, it is problematic in that non-uniformly forming a photoactive layer finally causes a lowering in PCE of the cell, mechanical endurance also lowers, and bonding force is not satisfactory.

Specifically, in case of thermoplastic polyurethane (TPU) used in the embodiment, it is an elastomeric material having surface roughness of 5.4 nm, the transmittance of visible light of 91% and a water contact angle of 78.1°, and having low surface roughness and high wettability, and thanks to its own high surface energy, as a flat substrate is coated with the material, the first electrode layer or an upper layer of a hole transport layer may be uniformly formed of a conductive polymer (PEDOT:PSS), and thanks to excellent interfacial junction between the substrate and the conductive polymer material formed, high conductivity of the upper layer may be realized, and mechanical endurance may be also realized under a tensile condition.

It was confirmed that even with elastic substrates of the same material, when the requirements for surface roughness and water contact angle were not met, the results affecting PCE improvement differed. Accordingly, as the selection of an elastic substrate which satisfies the requirements for the surface roughness or the water contact angle is most suitable, the improvement of PCE may be confirmed, and it is supported that the selection of the substrate in the whole constitutions of the organic solar cell has an influence on bonding among layers, or integrating (see [Table 1, 2]).

From the above, with respect to an elastic substrate which may be used in the present invention, the elastomeric material publicly known in the field of organic solar cells may be used, if it meets the requirements for surface roughness and a water contact angle.

Preferable one example includes one or more materials selected from a group consisting of thermoplastic polyurethane (TPU), a thermoplastic or thermosetting copolymer, polydimethylsiloxane (PDMS), an acryl foam tape (AFT), a silicone elastomer, polyimide, polyethylene isophthalate, polyethylene naphthalate, polyethylene terephthalate, cellulose, a shape memory polymer, and hydrogel.

The thermoplastic copolymer may be at least one selected from a group consisting of a styrene-butadiene (SB) copolymer, a styrene-butadiene-styrene (SBS) copolymer, a styrene-isoprene-styrene (SIS) copolymer, a styrene-ethylene-butylene-styrene (SEBS) copolymer, and styrene-butadiene rubber (SBR).

### 2) Electrical Charge Transport layer

With respect to the intrinsically stretchable organic solar cell of the present invention, an electrical charge transport layer is a transport layer composed of an organic material, and a transport layer composed of an inorganic material, and a transport layer composed of a mixture of the organic material and the inorganic material.

In the embodiment of the present invention, although the transport layer is described based on a transport layer composed of an organic material in a single form composed of one selected from a polymeric hole transport layer, a small molecular hole transport layer, a polymeric electron transport layer, and a small molecular electron transport layer, or in a mixed form thereof, the transport layer is not limited thereto.

Furthermore, the electrical charge transport layer of a polymeric or small molecular material is advantageous to improve bonding force among layers, and more preferably, the electrical charge transport layer is composed of a polymeric material.

The polymeric hole transport layer (HTL) includes one, or two or more materials selected from a group consisting of poly(3,4-ethylenedioxythiophene):poly(styrene sulfonate) (PEDOT:PSS), polyacetylene, polypyrrole, polyparaphenylene, polyaniline, a polythiophen group, a polytriarylamine group, a polymer of a conjugated polyelectrolyte group, a crosslinkable polymer of a tetraphenyldiamine group, and a bis(trimethylsilyl)amine-based polymer.

The polytriarylamine group may be poly(triaryl amine) (PTAA), or poly(9,9-dioctylfluorene-alt-N-(4-sec-butylphenyl)-diphenylamine) (TFB), and conjugated polyelectrolyte-K (CPE-K) may be used as the polymer of the conjugated polyelectrolyte group.

Also, in the embodiment of the present invention, the electron transport layer (ETL) may be formed into one or more layers by coating of a solution for formation of a polymeric or small molecular electron transport layer. At this time, the electron transport layer may be formed using one or more materials selected among electron transport layer materials for an n-type solution process each including a side chain to which an amino or ammonium functional group is attached. The materials having the amino functional group are PFN, F3N, and PDIN, and the material having the ammonium functional group is —F3N—X (X=Br, I, F, Cl)/PFN-X (X=Br, I, F, Cl)/-PDIN-X (X=O, N).

The solution for forming the polymeric or small molecular electron transport layer includes one or more materials selected from a group consisting of: poly[[2,7-bis(2-ethylhexyl)-1,2,3,6,7,8-hexahydro-1,3,6,8-tetraoxobenzo [lmn][3,8]phenanthroline-4,9-diyl]-2,5-thiophenediyl[9,9-bis [3′((N,N-dimethyl)-N-ethylammonium)]propyl]-9H-fluorene-2,7-diyl]-2,5-thiophenediyl] (PNDIT-F3N—Br), poly[(9,9-bis(3′-(N,N-dimethylamino)propyl)-2,7-fluorene)-alt-2,7-(9,9-dioctylfluorene)] (PFN), and 2,9-Bis[3-(dimethyloxidoamino) propyl]anthra[2,1,9-def:6,5,10-d′e′f]diisoquinoline-1,3,8,10(2H,9H)-tetrone (PDINO).

The electrical charge transport layer of the present invention may have a single form composed of one selected from a polymeric hole transport layer, a small molecular hole transport layer, a polymeric electron transport layer, and a small molecular electron transport layer, or a mixed form thereof, and more preferably, it may simultaneously comprise the polymeric hole transport layer (HTL) and the polymeric electron transport layer (ETL) so that PCE performance can be improved (see [Table 4]). At this time, the polymeric hole transport layer (HTL) and the polymeric electron transport layer (ETL) may be realized in a structure that makes their positions reversed each other.

### 3) Photoactive Layer

With respect to the intrinsically stretchable organic solar cell of the present invention, the organic photoactive layer may be formed of one, or a mixture of two or more materials selected from a group consisting of a polymeric conjugated donor, a small molecular conjugated donor, a polymeric conjugated acceptor, and a small molecular conjugated acceptor.

One example of the mixture of two or more materials may include a polymeric conjugated donor, and a polymeric conjugated acceptor, a small molecular conjugated acceptor, or a conjugated acceptor in a mixed form including two acceptors, and various kinds of mixing may be performed. However, in case of the single form, the layer may be composed of a polymeric conjugated compound.

The conjugated acceptor may have a single form composed of one, or a mixed form of two or more materials selected from a group consisting of poly(para-phenylene), polyacetylene, polypyrrole, polyvinylcarbazol, polyaniline, polyphenylenevinylene, and a fullerene and non-fullerene acceptor.

More preferably, with respect to the photoactive layer, in the embodiment of the present invention, a compound (PM6) represented by following Chemical Formula 1 is used as a polymeric conjugated donor.

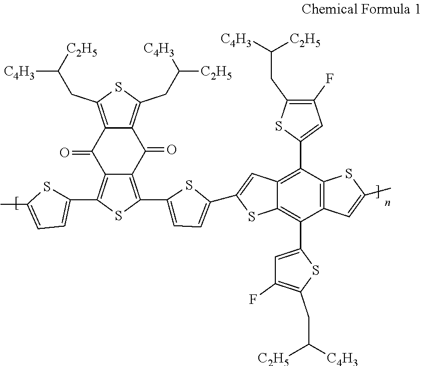

Furthermore, a non-fullerene conjugated acceptor (Y7) represented by following Chemical Formula 2 is used as a conjugated acceptor without being limited, and the conjugated acceptor may be selected from a group consisting of n-type non-fullerene acceptors (NFAs).

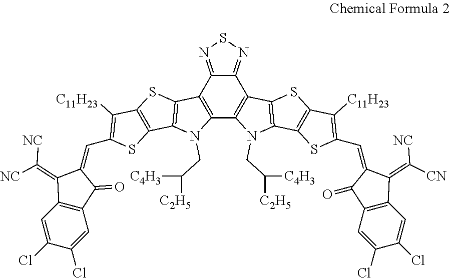

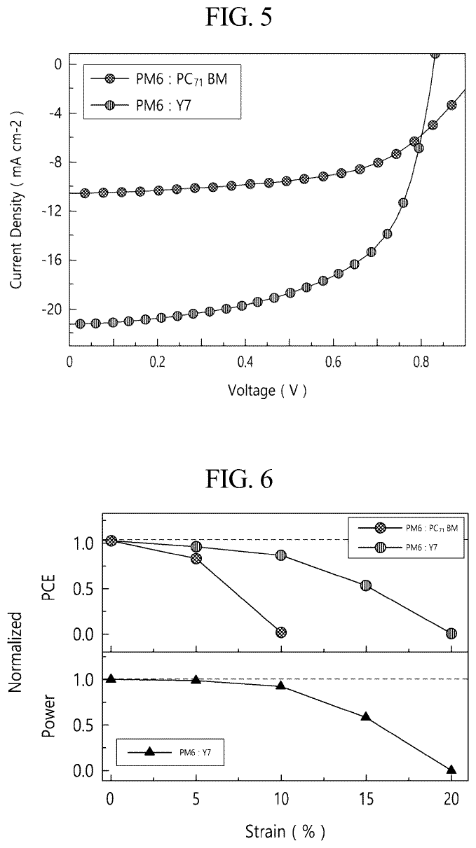

FIG. 5 and FIG. 6 present the results of evaluation on performance of the organic solar cell according to each constitution of the photoactive layer manufactured from the present invention, wherein it can be confirmed that an organic solar cell including a photoactive layer (PM6:Y7) shown in Example 1 shows to have high PCE (%), and in particular, a constant PCE level of 99% is maintained under the condition of 10% or below tensile strain. This result presents that there is possibility of uniformly providing power supply even under the condition of tensile strain when the organic solar cell is applied to the electronic equipment.

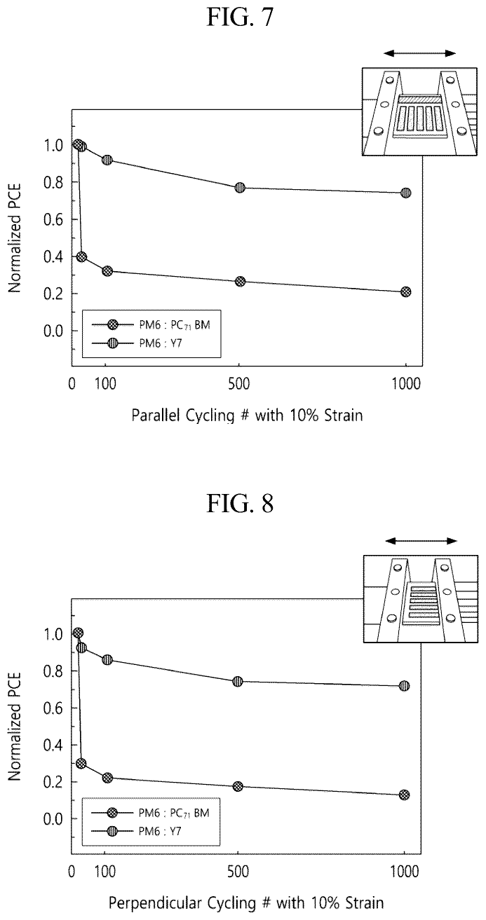

Furthermore, FIG. 7 shows the result of PCE performance (%) resulting from a tensile repetition experiment in a horizontal direction under fixed tensile strain with respect to the organic solar cell according to each constitution of the photoactive layer manufactured from the present invention, and FIG. 8 shows the result of PCE (%) resulting from a tensile repetition experiment in a vertical direction, wherein the results show that the organic solar cell including the photoactive layer (PM6:Y7) shown in Example 1 maintains 80% of initial PCE in the tensile repetition experiments in the horizontal direction and in the vertical direction on the basis of repetition 100 to 10,000 times.

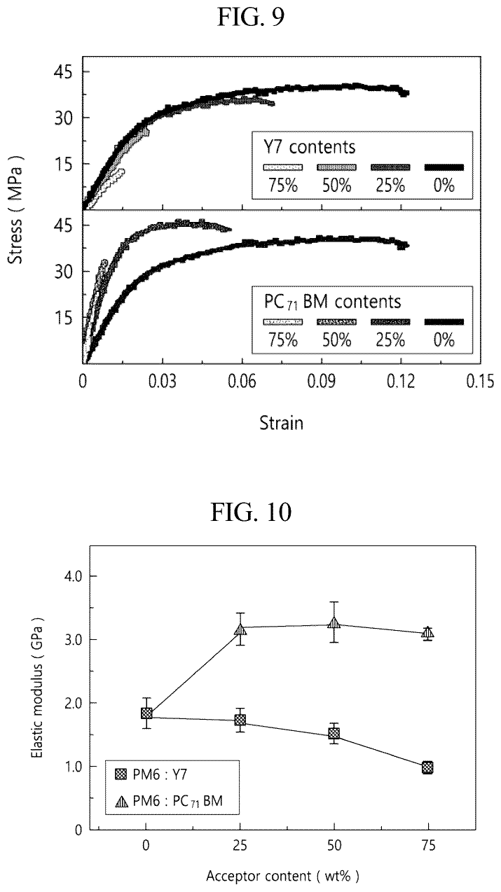

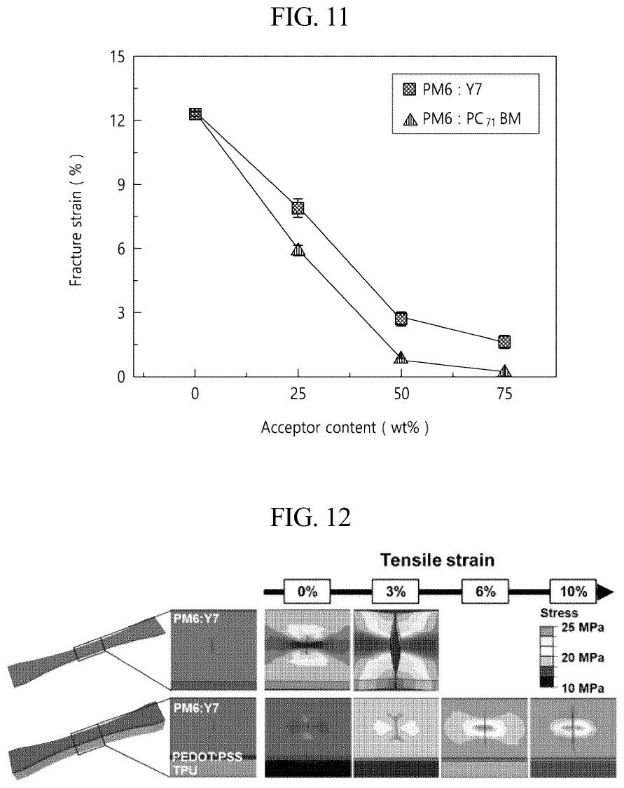

FIG. 9 shows tensile stress to strain curves concerning tensile strain according to respective contents of acceptors of the photoactive layer derived from the organic solar cell of the present invention, FIG. 10 shows a result of the elastic modulus concerning the tensile strain shown in FIG. 9, FIG. 11 shows the result of a fracture strain concerning the tensile strain shown in FIG. 9, wherein the results are based on the acceptors constituting the photoactive layer, and the elastic modulus and fracture strain according to each content of the acceptors, and in case of the organic solar cell having the photoactive layer (PM6:Y7) according to the embodiment, high mechanical stretchability is realized.

According to another embodiment, a weight ratio of a polymeric conjugated donor to a conjugated acceptor, which form the photoactive layer, is 1:10 to 10:1, preferably, a weight ratio of the polymeric conjugated donor to the conjugated acceptor is 1:5 to 5:1, and more preferably, a weight ratio of the polymeric conjugated donor to the conjugated acceptor is 1:3 to 3:1. At this time, the weight ratio of the polymeric conjugated donor to the conjugated acceptor functions as an important factor for causing mechanical endurance and stretchability to be most suitable, and when the weight ratio exceeds each range, brittleness may increase.

With respect to the photoactive layer, although it is also possible to use a photoactive layer (PM6:PC₇₁BM) consisting of a polymeric conjugated donor PM6, and a fullerene acceptor PC₇₁BM, due to the spherical fullerene acceptor, the photoactive layer tends to form aggregates having a sharp grain boundary and border without entanglement, so it has relatively high brittleness, and low cohesion energy.

On the contrary, since the photoactive layer (PM6:Y7) composed of the polymeric conjugated donor PM6, and the non-fullerene acceptor Y7 as a conjugated acceptor has a structure that is somewhat plane and hard due to a structural feature of the non-fullerene acceptor having a bulky 8-rings fused core (dithienothiophen[3.2-b]-pyrrolobenzothiadiazole), and a long branch-shaped alkyl chain, self-cohesive power is much weaker relatively than in the fullerene acceptor (PC₇₁BM).

Since this planar Y7 acceptor forms non-covalent bonds, F . . . S and F . . . H, with the compound of PM6 which is a fluorinated polymeric conjugated donor, an interaction between the non-covalent molecules may increase, and thus a stronger interfacial bonding property can be realized.

From the above, it can be confirmed that thanks to strong combination force between the polymeric conjugated donor and the non-fullerene acceptor which constitute the photoactive layer, the organic solar cell comprising the photoactive layer may maintain initial PCE even in the tensile repetition experiments under the condition of tensile strain. Thus, the acceptor constituting the photoactive layer, and its content are adjusted so that high mechanical endurance of the organic solar cell can be achieved.

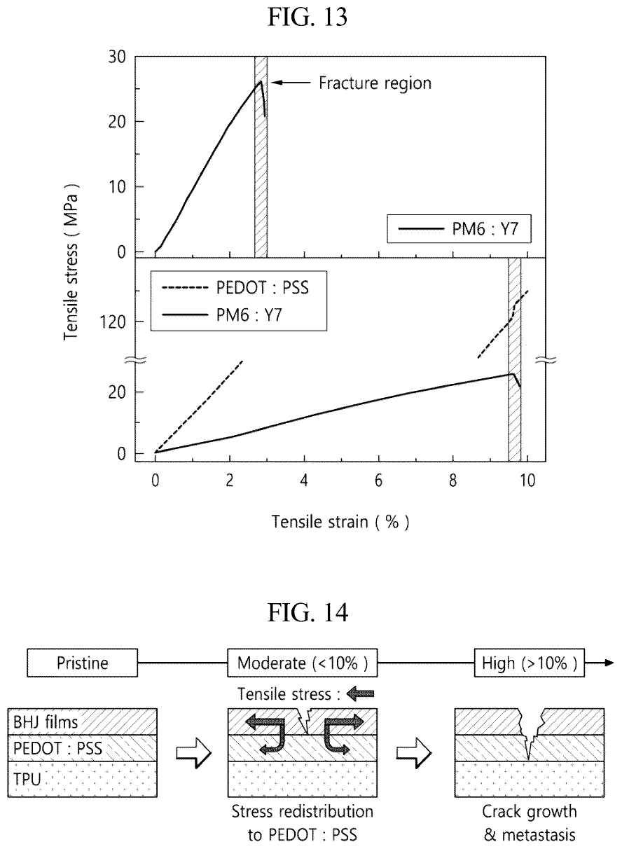

FIG. 12 shows perspective views of 3D models for a single film composed of the photoactive layer (PM6:Y7) of the present invention, and for a film in which the photoactive layer (PM6:Y7) is attached onto a surface consisting of TPU/PEDOT:PSS, showing the result of a finite element analysis for materializing a tensile stress distribution resulting from elongation, and FIG. 13 shows stress to strain curves of the films shown in FIG. 12, wherein it can be confirmed that the single film shows a 2.76% of fracture strain, and the film in a state of the photoactive layer being attached to the surface of PEDOT:PSS shows a 9.64% of fracture strain.

As a result thereof, in case of the single film consisting of the photoactive layer (PM6:Y7), since a tensile stress is easily concentrated on the edge of a crack, spreading of the crack may not be controlled, whereas in case of the film in which the photoactive layer (PM6:Y7) is attached onto the surface consisting of TPU/PEDOT:PSS, it may be confirmed that since the fracture strain increases largely, a strong combination between the photoactive layer attached and the surface consisting of TPU/PEDOT:PSS is formed.

FIG. 14 illustrates a conceptual view concerning formation of a crack formed by a progressive tensile repetition experiment for the organic solar cell comprising the film shown in FIG. 12 in which the photoactive layer (PM6:Y7) is attached onto the surface consisting of TPU/PEDOT:PSS, wherein when a strain occurs in case that the photoactive layer having a strong interfacial bonding property bonds to a non-attachment layer, the strain tends to uniformly distribute onto the photoactive layer, so the photoactive layer can endure much larger strains than when it exists as the film in an independent form.

### 4) Electrode Layer

With respect to the intrinsically stretchable organic solar cell of the present invention, the electrode layer may comprise a first electrode layer and a second electrode layer, and if one electrode layer selected from the first electrode layer or the second electrode layer constituting the electrode layer is a bottom electrode which is formed to be adjacent to a substrate, the other electrode layer will be formed into a top electrode, and their positions may be inverted each other.

At this time, as the first electrode layer or the second electrode layer is composed of a stretchable conductor selected from a polymer or stretchable metal, excellent stretchability is realized.

When the first electrode layer or the second electrode layer is composed of a polymer of PEDOT:PSS (poly(3,4-ethylenedioxythiophene):poly(styrene sulfonate)), it is preferable that the first electrode layer or the second electrode layer is subjected to acid treatment, and more preferably, it may further comprise one or more additives selected from a group consisting of dimethylsulfoxide (DMSO), polyethylene glycol (PEG), and a fluorinated surfactant.

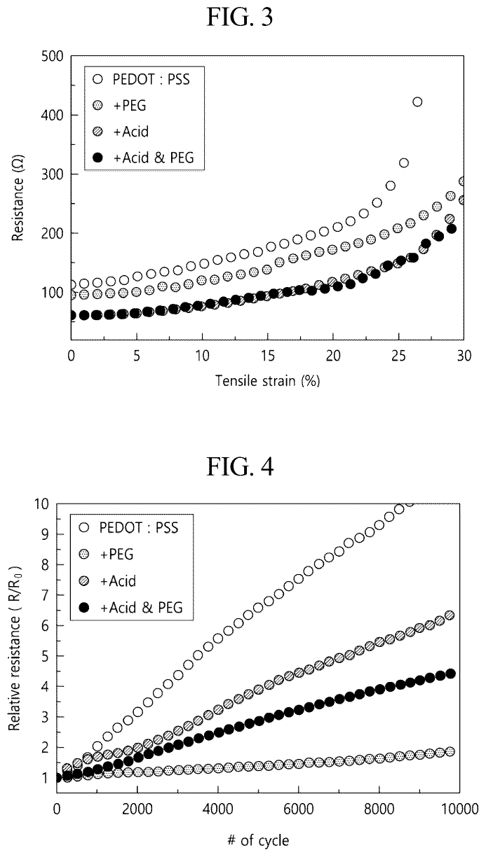

FIG. 3 shows, according to the embodiment of the present invention, resistance values resulting from initial tensile strains according to conditions for forming the first electrode layer and FIG. 4 shows relative resistance values resulting from the tensile repetition number of times, wherein when the first electrode layer is formed, in case that the layer of PEDOT:PSS (m-PH1000) is subjected to acid treatment or additive treatment, or both acid and additive (PEG) treatment, since it can be confirmed that a relatively low resistance value shows under the condition of a tensile repetition experiment on the basis of repetition 100 to 10,000 times, it can be confirmed that conductivity of the PEDOT:PSS (m-PH1000) layer is improved, and that stretchability and a mechanical physical property are also improved thanks to the improvement of surface wettability.

Furthermore, the first electrode layer or the second electrode layer is composed of a stretchable conductor including a stretchable metal, and in the embodiment of the present invention, as a preferably embodied form, since a liquid metal, preferably, eutectic gallium-indium (EGaIn) has low wettability concerning an organic thin film, the liquid metal of EGaln is fine-grained, so the first electrode layer or the second electrode layer may be formed into the shape of a minute pattern (˜200 μm) without any damage to the whole surface of a lower layer using a spray printing method in a liquefied state.

When the globular particle of single metal having a diameter of ˜4 mm is pulled up in a bell-like shape through an injector, due to its own very high surface tension (˜624 dyne/cm), the particle may not spread onto the thermoplastic polyurethane (TPU) substrate, and if tilting occurs due to a large bell size, the particle will be able to be removed completely from the TPU substrate. On the contrary, in case of the EGaIn liquid metal injected, a stable thin film is formed. At this time, when the particle of EGaIn which is fine-grained is applied thereto using a spray method, since a large sized oxidation layer is formed, it helps the particle to be fixed to a target substrate, and a thin and stable liquid electrode may be formed.

The EGaIn electrode formed by the spray printing method shows more excellent mechanical endurance and electrical characters than in a case in which a silver nanowire (AgNW) and a carbon nanotube (CNT) are used singly.

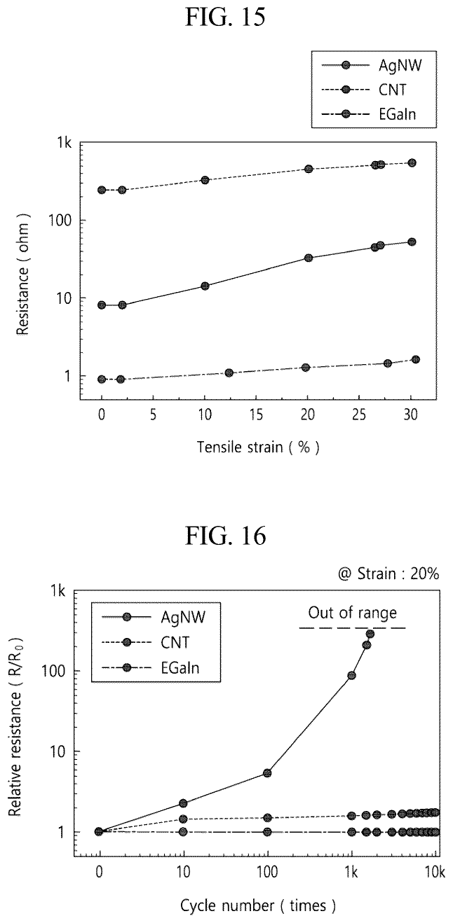

FIG. 15 shows changes in resistance values concerning tensile strain according to each material of the second electrode layer shown in the intrinsically stretchable organic solar cell of the present invention, and FIG. 16 shows changes in resistance values concerning the repetition number of times in a state of the tensile strain shown in FIG. 15 being fixed to be 20%, wherein an initial resistance value of the EGaIn electrode is 0.9Ω under a condition of the same lengths, and is remarkably smaller than 8.0Ω and 241.0Ω corresponding to an initial resistance value of a silver nanowire and an initial resistance value of a carbon nanotube, respectively.

According to tensile strain, resistance of the EGaIn electrode with respect to 30% tensile strain increases up to 1.7 times, whereas resistance of the silver nanowire (AgNW) electrode increases up to 6.5 times, and resistance of the carbon nanotube (CNT) electrode increases up to 2.3 times. What is more important is that as confirmed in FIG. 14, the EGaIn electrode has excellent mechanical restoration force because it maintains fixed resistance in a section before repetition 10,000 times in an experiment performed with respect to repetition 10,000 times in a state of tensile strain being fixed to be 20%.

Furthermore, as a result of evaluation on performance according to each material of the second electrode layer derived from the intrinsically stretchable organic solar cell according to the embodiment of the present invention, in case that the EGaIn electrode is used into a second electrode, the improvement of relatively excellent PCE performance can be confirmed (see [Table 5]).

Accordingly, the first electrode layer or the second electrode layer of the present invention may be used in a state of being mixed with a publicly known flexible electrode material, like a silver nanowire (AgNW), a carbon nanotube (CNT), and so on as well as a liquid metal.

Specifically, the first electrode layer or the second electrode layer of the present invention may be used in a single form composed of one, or a mixed form of two or more materials selected from a group consisting of hydrargyrum (Hg), gallium (Ga), indium (In), stannum (Sn), cesium (Cs), kalium (K), natrium (Na), rubidium (Rb), argentum (Ag), aluminum (Al), aurum (Au), eutectic gallium-indium (EGaIn), galinstan, cuprum (Cu), plumbum (Pb), bismuth (Bi), cadmium (Cd), a silver nanowire, a copper nanowire, a silicone nanowire, a carbon nanotube, and an alloy thereof.

The intrinsically stretchable organic solar cell of the present invention as described above shows a physical property which shows that 70% or more of initial PCE is maintained in the tensile repetition experiment on the basis of repetition 100 to 10,000 times.

### 5) Production of Stretchable Solar Cell

The present invention provides a method of manufacturing an intrinsically stretchable organic solar cell, the method comprising: preparing an elastic substrate which satisfies the requirements for surface roughness of 15 nm or below, and a water contact angle of 100° or below; forming, a first electrode layer, an electrical charge transport layer, an organic photoactive layer composed of a conjugated polymer, and a second electrode layer, which are piled up from the elastic substrate; and coating the first electrode layer or the second electrode layer with a solution containing a conductive polymer, or applying a solution containing a stretchable metal thereto, thereby improving interfacial junction.

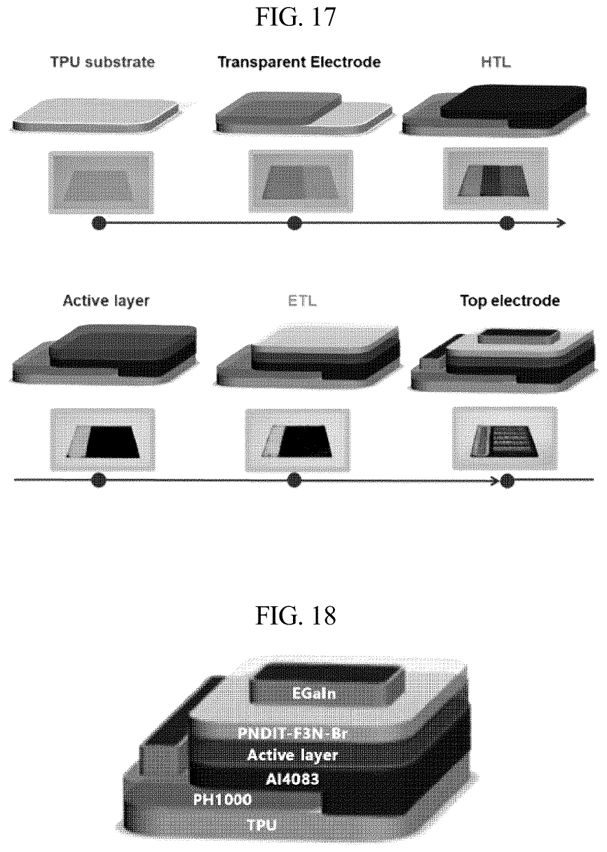

FIG. 17 illustrates, in steps, a manufacturing process of the intrinsically stretchable organic solar cell according to the other embodiment of the present invention, FIG. 18 shows a sectional image of the intrinsically stretchable organic solar cell produced by the manufacturing process, and explaining the constitutions based on Example 1, the organic solar cell has a normal structure in which the elastic substrate (TPU)/the first electrode layer (PEDOT:PSS, PH100)/the hole transport layer (PEDOT:PSS, AI4083)/the organic photoactive layer (PM6:Y7)/the electron transport layer (PNDIT-F3N—Br)/the second electrode layer (EGaIn) bond together.

Furthermore, in the present invention, with respect to the structure, it will be also possible to manufacture the organic solar cell having an inverted structure in which the positions of the first electrode layer and the second electrode layer are inverted each other, or the positions of the hole transport layer and the electron transport layer are also inverted each other.

Describing the manufacturing process according to each step illustrated in FIG. 17, the manufacturing method of the intrinsically stretchable organic solar cell according to the present invention comprises: a first step of forming a first electrode layer and a hole transport layer by successively coating an elastic substrate with a solution composed of a polymer; a second step of forming an organic photoactive layer composed of a conjugated polymer on the hole transport layer, wherein the photoactive layer is formed by coating of a solution containing one, or a mixture of two or more materials selected from a group consisting of a polymeric conjugated donor, a small molecular conjugated donor, a polymeric conjugated acceptor, and a small molecular conjugated acceptor; a third step of forming a polymeric electron transport layer by coating the photoactive layer with a solution for formation of the polymeric electron transport layer, and a fourth step of forming a second electrode layer by applying a solution containing a stretchable conductor onto the polymeric electron transport layer.

Hereinafter, the manufacturing method is described in detail according to each step.

If a material satisfies the requirements for surface roughness of 15 nm or below, and a water contact angle of 100° or below, it can be used in the elastic substrate used in the first step of the manufacturing method of the present invention, and one example thereof includes one or more materials selected from a group consisting of thermoplastic polyurethane (TPU), a thermoplastic or thermosetting copolymer, polydimethylsiloxane PDMS, an acryl foam tape (AFT), a silicone elastomer, polyimide, polyethylene isophthalate, polyethylene naphthalate, polyethylene terephthalate, cellulose, a shape memory polymer, and hydrogel.

One example of the thermoplastic copolymer includes one or more materials selected from a group consisting of a styrene-butadiene (SB) copolymer, a styrene-butadiene-styrene (SBS) copolymer, a styrene-isoprene-styrene (SIS) copolymer, a styrene-ethylene-butylene-styrene (SEBS) copolymer, and styrene-butadiene rubber (SBR), and the detailed description thereof is omitted because it is the same as described in the aforesaid elastic substrate.

In the first step, the hole transport layer may be formed from a solution containing one, or two or more materials selected from a group consisting of poly(3,4-ethylenedioxythiophene):poly(styrene sulfonate) (PEDOT:PSS), polyacetylene, polypyrrole, polyparaphenylene, polyaniline, a polythiophen group, a polytriarylamine group, a polymer of conjugated polyelectrolyte series, a crosslinkable polymer of tetraphenyldiamine group, and a bis(trimethylsilyl)amine-based polymer.

Furthermore, the first electrode layer formed on the substrate in the first step may composed of a stretchable conductor selected from a polymer or a stretchable metal, but more preferably, since the adjacent hole transport layer is formed from the solution containing a polymer, in order to improve bonding force, the first electrode layer is also formed using a solution containing a polymer.

According to the other embodiment of the present invention, the first electrode layer and the hole transport layer are composed of a polymer material, and more preferably, the first electrode layer is formed in such a manner that a part of the elastic substrate is coated with a first solution containing PEDOT:PSS (poly(3,4-ethylenedioxythiophene):poly(styrene sulfonate) (i.e., m-PH1000), and the hole transport layer (HTL) is formed in such a manner that the remaining region except the part of the substrate, and the first electrode layer are coated with a second solution containing PEDOT:PSS (i.e., AI4083), and a conductive polymer of the same material is used.

The first solution is a solution containing a conductive polymer in which PEDOT:PSS (poly(3,4-ethylenedioxythiophene):poly(styrene sulfonate) is included at a weight ratio of 1:1 to 1:10, the first electrode layer formed by coating of the first solution may be subjected to acid treatment for improvement of electrical conductivity. At this time, the acid treatment is performed using any one or more acids selected from a group consisting of citric acid (C₆H₈O₇), malic acid (C₄H₆O₅), tartaric acid (C₄H₆O₆), sulfuric acid (H₂SO₄), nitric acid (HNO₃), and perchlorate (HClO₄), and it is more preferable to use weak acid which enables a friendly environmental and much stable harmless process compared with strong acid.

The acid treatment may be performed in such a manner as to let the acidic solution fall onto the first electrode layer, and then to maintain the first electrode layer in such a state. After the acid treatment, washing and annealing processes may be performed. As one example, after the acid treatment is performed in such a manner as to let an acidic aqueous solution fall onto the first electrode layer and then to maintain such a state for 10 to 20 minutes, washing is performed for removal of each residual acid three times in the order of deionized (DI) water and ethanol, and annealing is performed for 10 to 20 minutes at 80 to 120° C. The annealing process may improve bonding force by drying the residual water.

Accordingly, as the acid treatment is carried out, crystallinity of a domain of PEDOT included in the first electrode layer increases so that conductivity of the first electrode layer can be improved, and PCE performance can be finally improved (see [Table 3]).

Furthermore, after the acid treatment is carried out, the first electrode layer is formed in such a manner as to further add one or more materials selected from a group consisting of dimethylsulfoxide (DMSO), polyethylene glycol (PEG), and a fluorinated surfactant, so wettability can be improved.

In the manufacturing method of the present invention, the second step shows forming the organic photoactive layer composed of a conjugated polymer by coating the hole transport layer with a solution containing one, or a mixture of two or more materials selected from a group consisting of a polymeric conjugated donor, a small molecular conjugated donor, a polymeric conjugated acceptor, and a small molecular conjugated acceptor.

One example of the case in which two or more materials are mixed may include various kinds of mixing, like mixing of the polymeric conjugated donor and the polymeric conjugated acceptor and mixing of the polymeric conjugated donor and a conjugated acceptor in a single form composed of the small molecular conjugated acceptor, or in a mixed form composed of said two acceptors. However, in case of the single form, it is realized from a polymeric conjugated compound.

The conjugated acceptor has a single form composed of one or a mixed form of two or more materials selected from a group consisting of poly(para-phenylene), polyacetylene, polypyrrole, polyvinylcarbazole, polyaniline, polyphenylenevinylene, and fullerene and non-fullerene acceptor, and more preferably, n-type non-fullerene acceptors (NFAs) may be used as the non-fullerene acceptor.

According to the other embodiment of the present invention, as the photoactive layer composed of the polymeric conjugated donor (PM6) and the non-fullerene acceptor (Y7) is formed, excellent mechanical physical properties can be confirmed in spite of repetitive tensile strains of PCE of the organic solar cell.

The third step of the manufacturing method of the present invention shows forming the electron transport layer composed of one or more layers by coating the organic photoactive layer formed in the second step with the solution for formation of the polymeric or small molecular electron transport layer.

At this time, as the electron transport layer materials, may be used one or more materials selected among electron transport layer materials for an n-type solution process each including a side chain into which an amino or ammonium functional group is added. The materials having the amino functional group correspond to PFN, F3N, and PDIN, and the material having the ammonium functional group corresponds to —F3N—X (X=Br, I, F, Cl)/PFN-X (X=Br, I, F, Cl)/-PDIN-X (X=O, N).

More preferably, the solution for formation of the polymeric or small molecular electron transport layer is a solution containing one or more materials selected from a group consisting of PNDIT-F3N—Br (Poly[[2,7-bis(2-ethylhexyl)-1,2,3,6,7,8-hexahydro-1,3,6,8-tetraoxobenzo [lmn][3,8]phenanthroline-4,9-diyl]-2,5-thiophenediyl[9,9-bis [3′((N,N-dimethyl)-N-ethylammonium)] propyl]-9H-fluorene-2,7-diyl]-2,5-thiophenediyl]), PFN (Poly[(9,9-bis(3′-(N,N-dimethylamino)propyl)-2,7-fluorene)-alt-2,7-(9,9-dioctylfluorene)]), and PDINO (2,9-Bis[3-(dimethyloxidoamino)propyl]anthra[2,1,9-def:6,5,10-d′e′f′] diisoquinoline-1,3,8,10(2H,9H)-tetrone), and the layer is formed by coating of the solution.

The electron transport layer according to the present invention is a polymeric transport layer in which a polymeric material is used, and in consideration of its stretchable physical property, as preferable one example, PNDIT-F3N—Br is used. PNDIT-F3N—Br, which is a methanol soluble polymer, is available to form a layer through a high temperature solution process and is able to improve stretchability and power conversion efficiency of the solar cell.

The manufacturing method described above may be carried out in a liquid phase, and a coating process may be carried out using any one selected from a group consisting of spin coating, spray coating, roll-to-roll coating, gravure coating, deep coating, slot die coating, and bar coating.

Specifically, coating carried out in each step of forming the first electrode layer, the hole transport layer, the organic photoactive layer, and the electron transport layer is a spin coating method, and the spin coating is carried out for 10 to 60 seconds at 1,000 to 3,000 rpm.

The fourth step of the manufacturing method of the present invention shows forming the second electrode layer composed of a stretchable conductor on the polymeric electron transport layer formed in the third step.

The stretchable conductor may be used in a single form composed of one, or a mixed form of two or more materials selected from a group consisting of hydrargyrum (Hg), gallium (Ga), indium (In), stannum (Sn), cesium (Cs), kalium (K), natrium (Na), rubidium (Rb), argentum (Ag), aluminum (Al), aurum (Au), eutectic gallium-indium (EGaIn), galinstan, cuprum (Cu), plumbum (Pb), bismuth (Bi), cadmium (Cd), and an alloy thereof.

Preferably, the liquid metal is used, and in the other embodiment of the present invention, the second electrode layer is formed using eutectic gallium-indium (EGaIn) having excellent conductivity and stretchability. At this time, since the liquid metal, preferably, the eutectic gallium-indium (EGaIn) has low wettability with respect to the organic thin film, the liquid metal particle is patterned by a spray printing method by being fine-grained so that the second electrode layer can be formed in the shape of a minute pattern (˜200 μm) without any physical injury to the whole surface of a lower layer.

Furthermore, the second electrode layer formed using the liquid metal may be also formed by an atmospheric-pressure solution process or a vacuum deposition process.

In case that the electrode layer is formed of a liquid metal using a drop process used generally, it may be problematic in that a droplet of the liquid metal may slide down or may be removed from the surface of a body to be layered, and doesn't spread to the surface of the body to be layered, but when the second electrode layer is formed by a coating method using spray printing, it is advantageous in that a stable layer may be formed, and tilting is also very stable.

As one example, the coating method using spray printing may be carried out using an airbrush siphon-feed type spray system, and an airbrush siphon-feed type deposition system may consist of: a pressure pump; a liquid metal storage unit; and a spray nozzle. That is, after the liquid metal is pulled up from the liquid metal storage unit via the pressure pump, the liquid metal may be spray-coated in such a manner as to spray it upon the substrate using a spray nozzle.

In the method of manufacturing the organic cellar cell according to the present invention, since the processes are mostly carried out using an atmospheric-pressure solution process, the consumption of energy is low, and excellent reproducibility and yield can be secured thanks to the integrated processes.

Moreover, the present invention provides an electronic device comprising the intrinsically stretchable organic solar cell having the aforesaid properties as an electrical power source.

Since the intrinsically stretchable organic solar cell realizes the physical property which shows that 70% or more of initial PCE is maintained in a tensile repetition experiment on the basis of repetition 100 to 10,000 times, it can be applied into a field related with any selected from a group consisting of sensors, electronic skins, flexible displays, and stretchable displays, and the sensors may comprise strain sensors, temperature sensors, pressure sensors, optical sensors, vibration sensors, biosensors, and so on. In particular, the intrinsically stretchable organic solar cell of the present invention can be usefully applied to cloth type, accessory type, or body attachment type wearable electronic devices aimed at skins, fibers, or curved surfaces.

Hereinafter, the present invention is described in more detail with examples and comparative examples.

However, the following examples are only intended for exemplifying the present invention, and the contents of the present invention are not limited to the following examples.

### Example 1

### Production of Organic Solar Cell

Prior to the solution containing PEDOT:PSS (Heraeus Clevios™ PH1000) was filtered through a 0.45 μm filter, and then was spin-coated on a thermoplastic polyurethane (TPU) elastomer in air (2000 rpm) to form a first electrode layer. The TPU elastomer as an elastic substrate has 5.4 nm of surface roughness of, 78.1° of a water contact angle, and 91% of transmittance at visible wavelength. The solution containing PEDOT:PSS (Heraeus Clevios™ PH1000) contained 5 volume % of dimethylsulfoxide (DMSO), 2 volume % of polyethyleneglycol (PEG), and 0.5 volume % of a zonyl fluorite surfactant (Zonyl FS-30) as additives and were stirred during the night before application. The DMSO improved electrical conductivity of PEDOT:PSS (PH1000), the PEG improved mechanical stretchability, and the FS-30 increased surface wettability. At this time, in order to improve conductivity by raising crystallinity of the domain of PEDOT, the film of PH1000 was treated by weak acid, citric acid. The elastic substrate was subjected to plasma treatment before execution of spin coating so that wettability concerning the PH1000 film could be improved.

After this, the TPU elastomer coated with the PEDOT:PSS (PH1000) was heated for 20 minutes at 100° C. in air, and a residual substance was cooled after being dried, then the PH1000 film was subjected to citric acid treatment for 20 minutes at 100° C., and thus spin coating and drying were again performed.

Next, a surface of TPU/PEDOT:PSS (PH1000) was subjected to ozone plasma treatment for 45 seconds, and then, a layer of PEDOT:PSS ((Heraeus Clevios™ AI4083) constituting a second layer was spin-coated on the surface throughout its entire area for 40 seconds at 2500 rpm. Continuously, a photoactive layer and an electron transport layer were spin-coated. A mixture in which a polymeric donor (PM6, 1-Materials) represented by following Chemical Formula 1, and a non-fullerene acceptor (Y7, Derthon) represented by following Chemical Formula 2 were included at a weight ratio of 1:1 was stirred for at least 5 hours in a blend of CB (containing 0.5 volume % of CN) at a total concentration of 20 mg/ [symbol] , was purified by 0.2 μm of a PTFE filter, and was then spin-coated on a surface of TPU/PEDOT:PSS (PH1000)/PEDOT:PSS (AI4083) for 40 seconds at 2000 rpm.

A layer of PM6:Y7 (1:1, w/w) was spin-coated with the blend of CB (containing 0.5 volume % of CN) at a total concentration of 22 mg/ [symbol] for 40 seconds at 2000 rpm, and then a solution of PNDIT-F3N—Br having a total concentration of 1 mg/ [symbol] was produced in methanol, was stirred for 6 hours, and was then spin-coated on the photoactive layer for 40 seconds at 2000 rpm. At this time, a small piece of the PDMS film was used in patterning the photoactive layer and the electron transport layer (ETL) piled up from the TPU elastomer film. Finally, in order to realize elaborate patterning, the EGaIn liquid metal was sprayed-coated on the electron transport layer (ETL) through a shadow deposition mask, so an organic solar cell composed of the layer of TPU/PEDOT:PSS (PH1000)/PEDOT:PSS (AI4083)/PM6:Y7/PNDIT-F3N—Br/EGaIn was manufactured.

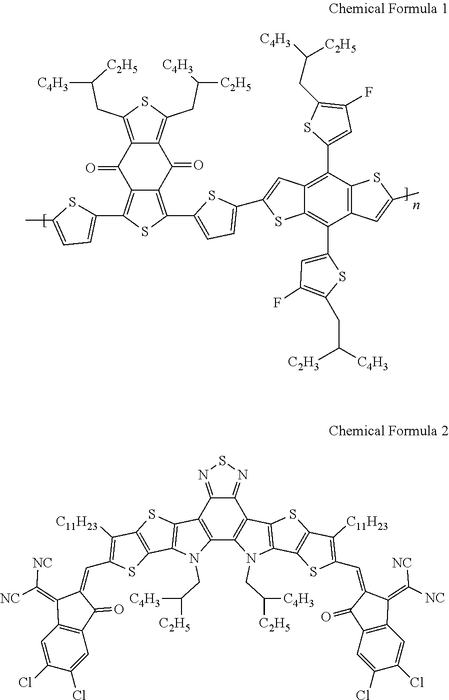

### Example 2

An organic solar cell was produced by the same method as that performed in said Example 1 except that a material of polydimethylsiloxane (PDMS) in the same ranges as those of surface roughness and a water contact angle of the elastic substrate used in said Example 1 was used.

### Example 3

An organic solar cell was produced by the same method as that performed in said Example 1 except that a material of an acryl foam tape (AFT) in the same ranges as those of surface roughness and a water contact angle of the elastic substrate used in said Example 1 was used.

### Example 4

An organic solar cell was produced by the same method as that performed in Example 1 except that when a photoactive layer was produced, a mixture including a polymeric donor (PM6) and a fullerene acceptor (PC₇₁BM) at a weight ratio of 1:1.2 was stirred in a blend of CB (containing 1 volume % of DIO) at a total concentration of 22 mg/ [symbol] , and then spin coating (for 40 seconds at 2000 rpm) was performed. A compound represented by following Chemical Formula 3 was used in the fullerene acceptor (PC₇₁BM).

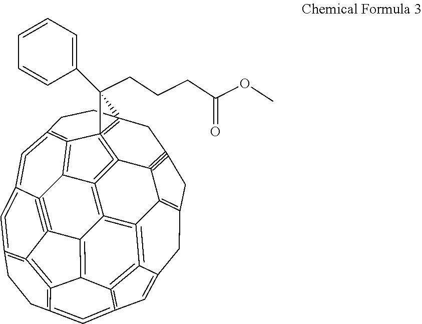

### Example 5

An organic solar cell was produced using the same method as in Example 1, except that a TPU material with a surface roughness of 1.8 nm and a water contact angle of 74.2° was used for the elastic substrate instead of the one used in Example 1.

### Comparative Example 1

An organic solar cell was produced by the same method as that performed in said Example 1 except that a material of a polydimethylsiloxane (PDMS) substrate having 15.4 nm of surface roughness of, 106.9° of a water contact angle, and 97% of transmittance was used.

### Comparative Example 2

An organic solar cell was produced by the same method as that performed in said Example 1 except that the material of an acryl foam tape (AFT) substrate having 22.9 nm of surface roughness, 112.2° of a water contact angle, and 91% of transmittance was used.

### Comparative Example 3

An organic solar cell was produced using the same method as in Example 1, except that a TPU material with a surface roughness of 2.4 nm and a water contact angle of 103.5° was used for the elastic substrate instead of the one used in Example 1.

### Comparative Example 4

An organic solar cell was produced using the same method as in Example 1, except that a TPU material with a surface roughness of 15.3 nm and a water contact angle of 72.5° was used for the elastic substrate instead of the one used in Example 1.

### Comparative Example 5

An organic solar cell was produced using the same method as in Example 1, except that a TPU material with a surface roughness of 16.1 nm and a water contact angle of 104.6° was used for the elastic substrate instead of the one used in Example 1.

### Comparative Example 6

An organic solar cell was produced by the same method as that performed in said Example 1 except that making of a first electrode layer was performed without a layer of PH1000 being treated by citric acid.

### Comparative Example 6

An organic solar cell was produced by the same method as that performed in said Example 1 except that unlike said Example 1, neither hole transport layer (HTL) nor electron transport layer (ETL) was formed.

### Comparative Example 8

An organic solar cell was produced by the same method as that performed in said Example 1 except that unlike said Example 1, a hole transport layer (HTL, AI4083) was formed, and no electron transport layer (ETL) was formed.

### Comparative Example 9

An organic solar cell was produced by the same method as that performed in said Example 1 except that unlike said Example 1, an electron transport layer (ETL, PNDIT-F3N—Br) was formed, and no hole transport layer (HTL) was formed.

### Comparative Example 1

An organic solar cell was produced by the same method as that performed in said Example 1 except that a second electrode layer was formed using only a silver nanowire instead of the EGaln liquid metal used in the step of forming the second electrode layer composed of the EGaIn liquid metal used in said Example 1.

### Comparative Example 11

An organic solar cell was produced by the same method as that performed in said Example 1 except that a second electrode layer was formed using only a carbon nanotube instead of the EGaln liquid metal used in the step of forming the second electrode layer composed of the EGaln liquid metal used in said Example 1.

### Experimental Example 1

### Evaluation on Performance of Organic Solar Cell According to Each Elastic Substrate

An organic solar cell was produced by the same method as that performed in Example 4 except that in order to make an experiment in each influence of elastic substrates on performance with respect to production of the organic solar cell, the different kinds of substrates were used.

TABLE 1

| | | | | organic |
|---|---|---|---|---|
| | elastic | surface | water contact | photoactive |
| | substrate | roughness | angle | laye |
| Example 1 | TPU | 5.4 nm | 78.1° | PM6:Y7 |
| Example 2 | PMDS | 5.4 nm | 78.1° | PM6:Y7 |
| Example 3 | AFT | 5.4 nm | 78.1° | PM6:Y7 |
| Example 4 | TPU | 5.4 nm | 78.1° | PM6 + PC71BM |
| Example 5 | TPU | 1.8 nm | 74.2° | PM6 + PC71BM |
| Comparative | PMDS | 15.4 nm | 106.9° | PM6:Y7 |
| Example 1 | | | | |
| Comparative | AFT | 22.9 nm | 112.2° | PM6:Y7 |
| Example 2 | | | | |
| Comparative | TPU | 2.4 nm | 103.5° | PM6 + PC71BM |
| Example 3 | | | | |
| Comparative | TPU | 15.3 nm | 72.5° | PM6 + PC71BM |
| Example 4 | | | | |
| Comparative | TPU | 16.1 nm | 104.6° | PM6 + PC71BM |
| Example 5 | | | | |

TABLE 2

| | | | Jsc | | |
|---|---|---|---|---|---|
| Substrate | | Voc (V) | (mA cm⁻²) | FF | PCEₘₐₓ (%) |
| Example 4 | TPU | 0.97 | 10.93 | 0.59 | 6.27 |
| Example 5 | TPU | 0.97 | 10.93 | 0.59 | 6.27 |
| Comparative | PDMS | 0.97 | 10.10 | 0.47 | 4.57 |
| Example 1 | | | | | |
| Comparative | AFT | 0.96 | 9.32 | 0.39 | 3.49 |
| Example 2 | | | | | |
| Comparative | TPU | 0.93 | 9.32 | 0.46 | 4.01 |
| Example 3 | | | | | |
| Comparative | TPU | 0.07 | 8.93 | 0.25 | 0.15 |
| Example 4 | | | | | |
| Comparative | TPU | 0.03 | 7.14 | 0.25 | 0.05 |
| Example 5 | | | | | |

Based on the result shown in said Table 1, 2, it was confirmed that according to the selection of the elastic substrate which meets the requirements for surface roughness, transmittance, and a water contact angle, power conversion efficiency was improved up to 50% or more greatly.

### Experimental Example 2

### Evaluation on Performance of Organic Solar Cell Resulting From Whether or Not to Perform Treatment of Acids for Formation of First Electrode Layer

In order to make an experiment in an influence on performance of an organic solar cell, an organic solar cell was produced by the same method as that performed in Example 4 except that when a first electrode layer is formed, a layer of PH1000 was subjected to acid treatment, and the other layer of PH1000 wasn't subjected to acid treatment.

TABLE 2

| | | | Sheet | | | | PCEₘₐₓ |
|---|---|---|---|---|---|---|---|
| | | Citric | Resistance | Voc | Jsc | | (PCE_{avg}) |
| First Electrode Layer | | acid | (Ω/sq) | (V) | (mA cm⁻²) | FF | (%) |
| Example 4 | PEDOT:PSS | treated | 34 | 0.97 | 10.93 | 0.59 | 6.27 |
| | | | | | | | (6.01) |
| Comparative | PEDOT:PSS | non- | 65 | 0.95 | 10.54 | 0.55 | 5.55 |
| Example 3 | | treated | | | | | (5.27) |

Based on the result shown in said Table 3, it could be confirmed that the organic solar cell, in which the layer of PEDOT:PSS (modified PH1000) was subjected to citric acid treatment when the first electrode layer was formed, showed more improved PCE performance than that of the organic solar cell manufactured without citric acid treatment.

### Experimental Example 3

### Evaluation on Performance of Organic Solar Cell Resulting From Treatment of Additive for Formation of First Electrode Layer

An organic solar cell was produced by the same method as that performed in Example 4 except that with respect to production of the organic solar cell, when a first electrode layer was formed, a layer of PH1000 was treated by acid and/or polyethyleneglycol (PEG) was included as an additive.

As a result, FIG. 3 shows resistance values resulting from initial tensile strains, wherein it was confirmed that the first electrode layer formed in such a manner as to perform acid treatment, or to perform acid treatment and to further comprise an additive (PEG) had low resistance values with respect to the tensile strains. Also, FIG. 4 shows relative resistance values according to the tensile repetition number of times, wherein it was confirmed that when the first electrode layer was formed, the resistance values became lower relatively in case that the layer of PH1000 was subjected to acid treatment only, or to additive (PEG) treatment only, or to both acid treatment and additive (PEG) treatment than in case that PH1000 was used without any treatment, so conductance of PEDOT:PSS (modified PH1000) was improved, and stretchability and mechanical physical properties were improved owing to improvement of surface wettability.

### Experimental Example 4

### Evaluation on Performance of Organic Solar Cell Resulting From Formation of Polymer Transport Layer

An organic solar cell was produced by the same method as that performed in Example 4 except that in order to make an experiment in an influence of the formation of a polymer transport layer on performance of the organic solar cell with respect to production of the organic solar cell, it was produced with or without the constitutions of a hole transport layer and/or an electron transport layer as presented in Table 4 below.

TABLE 3

| | | | | | | PCEₘₐₓ |
|---|---|---|---|---|---|---|
| | | | Voc | Jsc | | (PCE_{avg}) |
| Division | HTL | ETL | (V) | (mA cm⁻²) | FF | (%) |
| Example 4 | AI4083 | PNDIT- | 0.97 | 10.93 | 0.59 | 6.27 |
| | | F3N-Br | | | | (6.01) |
| Comparative | None | None | 0.48 | 7.22 | 0.27 | 0.92 |
| Example 4 | | | | | | (0.78) |
| Comparative | AI4083 | None | 0.62 | 9.96 | 0.39 | 2.45 |
| Example 5 | | | | | | (2.18) |
| Comparative | None | PNDIT- | 0.75 | 10.64 | 0.47 | 3.73 |
| Example 6 | | F3N-Br | | | | (3.43) |

Based on the result shown in Table 4 above, it was confirmed that when the polymeric hole transport layer and the polymeric electron transport layer were formed, total performance of the organic solar cell, in particular, PCE performance was improved.

### Experimental Example 5

### Evaluation on Performance of Organic Solar Cell According to Each Material of Photoactive Layer

According to materials for the formation of a photoactive layer with respect to production of an organic solar cell, an experiment concerning an influence on performance of the organic solar cell was performed. At this time, experiments concerning the performance of photoelectro-motive force of the organic solar cells each comprising the photoactive layer (PM6:Y7) as shown in Example 1, and the photoactive layer (PM6:PC₇₁BM) as shown in Example 4 were performed.

FIG. 5 shows the result of current density (mA cm⁻²) of the organic solar cell according to each constitution of the photoactive layer manufactured from the present invention, wherein it was confirmed that the organic solar cell comprising the photoactive layer (PM6:Y7) as shown in Example 1 had high PCE, and FIG. 6 shows the result of PCE performance (%) resulting from the intensity of tensile strain (%) with respect to the organic solar cell according to each constitution of the photoactive layer manufactured from the present invention, wherein the organic solar cell comprising the photoactive layer (PM6:Y7) as shown in Example 1 had higher durability concerning tensile strains than that of the organic solar cell comprising the photoactive layer of PM6:PC₇₁BM as shown in Example 4. In particular, PCE performance was maintained up to less than 20% in the maximum value at 10% tensile strain (%), and in particular, fixed PCE performance in a constant PCE level of 99% is maintained under the condition of 10% or below tensile strain (strain).

FIG. 7 shows the result of PCE performance (%) resulting from a tensile repetition experiment in a horizontal direction under fixed tensile strain with respect to the organic solar cell according to each constitution of the photoactive layer manufactured from the present invention, and FIG. 8 showing the result of that in a vertical direction, wherein the organic solar cell comprising the photoactive layer (PM6:Y7) shown in Example 1 maintained 80% of initial PCE performance in each case of the tensile repetition experiments in the horizontal direction and the vertical direction on the basis of repetition 100 to 10,000 times.

Also, FIG. 9 to FIG. 11 show results concerning tensile physical properties according to each constitution of the acceptors of the photoactive layers with respect to the organic solar cells manufactured in Examples 1 and 4, wherein it was confirmed that in order to realize high mechanical endurance of the organic solar cells, the acceptors constituting the photoactive layers, and their respective contents were adjusted so that it could be achieved.

### Experimental Example 6

### Evaluation on Performance of Organic Solar Cell According to Each Material for Formation of Second Electrode Layer

In order to make an experiment in an influence of each material for formation of the second electrode layer on performance with respect to the production of an organic solar cell, the organic solar cell was produced by the same method as that performed in Example 4 except that different electrode materials were used as presented in Table 5 below.

TABLE 4

| | | | | | PCEₘₐₓ |
|---|---|---|---|---|---|
| Second Electrode | | Voc | Jsc | | (PCE_{avg}) |
| Layer | | (V) | (mA cm⁻²) | FF | (%) |
| Example 4 | EGaIn | 0.88 | 11.16 | 0.57 | 6.15 (5.60) |
| Comparative | AgNW | 0.75 | 9.23 | 0.36 | 2.86 (2.47) |
| Example 7 | | | | | |
| Comparative | CNT | 0.37 | 3.24 | 0.25 | 0.33 (0.30) |
| Example 8 | | | | | |

Based on the result shown in said Table 5, it was confirmed that when the second electrode layer using the liquid metal of EGaln was formed, PCE was remarkably excellent. The result also showed that the second electrode layer using the liquid metal of EGaln was formed on the surface without a solvent, whereas in the other cases, since the second electrode layer was applied in a solution phase under an isopropyl solvent. It is judged that the solvent greatly degrades the adjacent photoactive layer and the transport layer.

As previously described, although in the detailed description of the invention, having been described the detailed exemplary embodiments of the present invention, it will be obvious to those skilled in the art that various variations and modifications can be made within the scope of the technical ideas of the present invention, and it should be apparent that these variations and modifications fall under the scope of the appended claims.

What is claimed is:

1. A method for manufacturing an intrinsically stretchable organic solar cell with enhanced interfacial bonding, comprising:
preparing an elastic substrate with high light transmittance of 90% or more in the range of 380 to 900 nm,
forming a first electrode layer, a charge transport layer, an organic photoactive layer consisting of a conjugated polymer, and a second electrode layer on the elastic substrate, the first electrode layer or the second electrode layer is formed by coating a conductive polymer-containing solution or applying a stretchable metal-containing solution,
wherein the elastic substrate satisfies a surface roughness of 15 nm or less and a water contact angle of 100° or less.

2. The method for manufacturing an intrinsically stretchable organic solar cell according to claim 1, wherein the elastic substrate includes one or more materials selected from a group consisting of thermoplastic polyurethane (TPU), a thermoplastic or thermosetting copolymer, polydimethylsiloxane (PDMS), an acryl foam tape (AFT), a silicon elastomer, polyimide, polyethylene isophthalate, polyethylene naphthalate, polyethylene terephthalate, cellulose, a shape memory polymer, and hydrogel.

3. The method for manufacturing an intrinsically stretchable organic solar cell according to claim 2, wherein the thermoplastic copolymer includes one or more materials selected from a group consisting of a styrene-butadiene (SB) copolymer, a styrene-butadiene-styrene (SBS) copolymer, a styrene-isoprene-styrene (SIS) copolymer, a styrene-ethylene-butylene-styrene (SEBS) copolymer, and styrene-butadiene rubber (SBR).

4. The method for manufacturing an intrinsically stretchable organic solar cell according to claim 1, wherein the charge transport layer is formed by coating a polymer-based or small molecule-based hole transport layer formation solution to form a hole transport layer (HTL), or by coating a polymer-based or small molecule-based electron transport layer formation solution to form one or more layers of electron transport layer (ETL).

5. The method for manufacturing an intrinsically stretchable organic solar cell according to claim 4, wherein the hole transport layer (HTL) is formed from a polymer-based hole transport layer formation solution containing one or more selected from a group consisting of PEDOT:PSS (poly(3,4-ethylenedioxythiophene):poly(styrene sulfonate)), polyacetylene, polypyrrole, poly-para-phenylene, polyaniline, polythiophene-based, polytriarylamine-based, conjugated polyelectrolyte-based polymers, crosslinkable polymers of tetraphenyldiamine-based, and bis(trimethylsilyl)amine-based polymers.

6. The method for manufacturing an intrinsically stretchable organic solar cell according to claim 5, wherein the polymer-based hole transport layer is composed of PEDOT:PSS (poly(3,4-ethylenedioxythiophene):poly(styrene sulfonate)) and further includes one or more additives selected from a group consisting of dimethyl sulfoxide (DMSO), polyethylene glycol (PEG), and fluorine-based surfactants.

7. The method for manufacturing an intrinsically stretchable organic solar cell according to claim 4, wherein the electron transport layer includes one or more selected from a group consisting of PNDIT-F3N—Br (Poly[[2,7-bis(2-ethylhexyl)-1,2,3,6,7,8-hexahydro-1,3,6,8-tetraoxobenzo[lmn][3,8]phenanthroline-4,9-diyl]-2,5-thiophenediyl[9,9-bis[3′((N,N-dimethyl)-N-ethylammonium)]propyl]-9H-fluorene-2,7-diyl]-2,5-thiophenediyl]), PFN (Poly [(9,9-bis(3′-(N,N-dimethylamino)propyl)-2,7-fluorene)-alt-2,7-(9,9-dioctylfluorene)]), and PDINO (2,9-Bis[3-(dimethyloxidoamino)propyl]anthra[2,1,9-def:6,5,10-d′e′f′]diisoquinoline-1,3,8,10(2H,9H)-tetrone).

8. The method for manufacturing an intrinsically stretchable organic solar cell according to claim 1, wherein the organic photoactive layer is a combination of one or more selected from a group consisting of polymer conjugated donors, small molecule conjugated donors, polymer conjugated acceptors, and small molecule conjugated acceptors.

9. The method for manufacturing an intrinsically stretchable organic solar cell according to claim 8, wherein the conjugated acceptor is one or a mixture of two or more selected from a group consisting of poly(para-phenylene), polyacetylene, polypyrrole, polyvinylcarbazole, polyaniline and polyphenylenevinylene, fullerene and non-fullerene acceptors.

10. The method for manufacturing an intrinsically stretchable organic solar cell according to claim 1, wherein the first electrode layer or the second electrode layer is made of a stretchable conductor selected from polymers or stretchable metals.

11. The method for manufacturing an intrinsically stretchable organic solar cell according to claim 10, wherein the first electrode layer or the second electrode layer is formed from a conductive polymer-containing solution including PEDOT:PSS (poly(3,4-ethylenedioxythiophene):poly(styrene sulfonate)) in a weight ratio of 1:1 to 10.

12. The method for manufacturing an intrinsically stretchable organic solar cell according to claim 11, wherein the first electrode layer or the second electrode layer is acid-treated.

13. The method for manufacturing an intrinsically stretchable organic solar cell according to claim 12, wherein the acid treatment is performed with one or more selected from a group consisting of citric acid (C₆H₈O₇), malic acid (C₄H₆O₅), tartaric acid (C₄H₆O₆), sulfuric acid (H₂SO₄), nitric acid (HNO₃), and perchloric acid (HClO₄).

14. The method for manufacturing an intrinsically stretchable organic solar cell according to claim 12, wherein the first electrode layer or the second electrode layer further includes one or more additives selected from a group consisting of dimethyl sulfoxide (DMSO), polyethylene glycol (PEG), and fluorine-based surfactants.

15. The method for manufacturing an intrinsically stretchable organic solar cell according to claim 10, wherein the first electrode layer or the second electrode layer is formed from a stretchable metal-containing solution containing one or a mixture of two or more selected from a group consisting of mercury (Hg), gallium (Ga), indium (In), tin (Sn), cesium (Cs), potassium (K), sodium (Na), rubidium (Rb), silver (Ag), aluminum (Al), gold (Au), eutectic gallium-indium (EGaIn), Galinstan, copper (Cu), lead (Pb), bismuth (Bi), cadmium (Cd), silver nanowires, copper nanowires, silicon nanowires, carbon nanotubes, and alloys thereof.

16. The method for manufacturing an intrinsically stretchable organic solar cell according to claim 15, wherein the first electrode layer or the second electrode layer is patterned with eutectic gallium-indium (EGaIn).
